(19) United States
(12) Patent Application Publication
(10) Pub. No.: US 2025/0283209 A1
(43) Pub. Date: Sep. 11, 2025

(54) ION BEAM DEPOSITION

(71) Applicant: Plasma-Therm NES LLC, St. Petersburg, FL (US)

(72) Inventors: Sarpangala Hariharakeshava Hegde, Fremont, CA (US); Russell Westerman, Land O'Lakes, FL (US)

(73) Assignee: Plasma-Therm NES LLC, St. Petersburg, FL (US)

(21) Appl. No.: 19/072,482

(22) Filed: Mar. 6, 2025

Related U.S. Application Data
(60) Provisional application No. 63/563,389, filed on Mar. 10, 2024.

(51) Int. Cl. C23C 14/46; C23C 14/34; C23C 14/50

(52) U.S. Cl. CPC C23C 14/46; C23C 14/3442; C23C 14/505

(57) ABSTRACT

The present disclosure provides a method for depositing material onto a substrate. The method comprising the steps of placing the substrate onto a substrate stage in a vacuum chamber. Using a plasma source to generate ions within the vacuum chamber. The generated ions from the plasma source are collimated using a first collimator. The collimated ions are directed as a broad ion beam at a target within the vacuum chamber. Material is sputtered from the target toward the substrate as part of a deposition plume using the collimated broad ion beam. A second collimator is placed between the target and the substrate within the vacuum chamber. The sputtered material from the deposition plume is collimated using the second collimator. The substrate is exposed to the collimated sputtered material from the deposition plume.

### CROSS-REFERENCE TO RELATED APPLICATION

The present application claims priority to U.S. Provisional Patent Application No. 63/563,389 filed on Mar. 10, 2024, the contents of which are hereby incorporated by reference in their entirety.

### TECHNICAL FIELD

The present disclosure relates to the field of charged particle sources including broad-beam ion sources for ion beam deposition.

### BACKGROUND

FIG. 1 illustrates a typical ion beam deposition (IBD) system. In an IBD process, a target is placed in front of an ion source. A collimated narrow focused ion beam impinges on the target causing a sputtering of target material in a deposition plume towards a substrate on a substrate stage. The deposition plume has target material impinging on the substrate at a range of angles.

As shown in FIG. 2, a portion of the target material impinging on the substrate is arriving not perpendicularly to the substrate surface. The divergent (not perpendicular) non-uniform sputtered species land on the substrate and result in a buildup of sputtered material on the sidewalls of trenches on the substrate before sputtered material can fill the bottom of the trenches. In addition, the deposition has in-board and out-board asymmetry.

### SUMMARY OF THE INVENTION

In accordance with an embodiment, the present disclosure relates to using an ion beam deposition process wherein a collimated broad ion beam impinges on a target. Then, a physical collimator is placed between the deposition plume and a substrate on the substrate stage. The physical collimator results in the impinging deposition plume material that deposits on the substrate to fill the bottom of trenches on the substrate prior to building on the sides of the trenches and reduces in-board and out-board asymmetry in the deposition on the substrate from the deposition plume.

According to another aspect of an embodiment of the present disclosure method for depositing material onto a substrate, comprising the steps of placing the substrate onto a substrate stage in a vacuum chamber; generating ions using a plasma source within the vacuum chamber; collimating the generated ions from the plasma source using a first collimator; directing a collimated broad ion beam of the collimated ions at a target within the vacuum chamber; sputtering material from the target toward the substrate as part of a deposition plume using the collimated broad ion beam; placing a second collimator between the target and the substrate within the vacuum chamber; collimating the sputtered material from the deposition plume using the second collimator; and exposing the substrate to the collimated sputtered material from the deposition plume.

According to another aspect of an embodiment of the present disclosure method for depositing material onto a substrate, comprising the steps of placing the substrate having a plurality of etched holes onto a substrate stage in a vacuum chamber; generating ions using a plasma source within the vacuum chamber; collimating the generated ions from the plasma source using a first collimator; directing a non-focused collimated broad ion beam of the collimated ions at a target within the vacuum chamber; sputtering material from the target toward said substrate having the plurality of etched holes as part of a deposition plume using the non-focused collimated broad ion beam; placing a second collimator between the target and sad substrate having the plurality of etched holes within the vacuum chamber; collimating the sputtered material from the deposition plume using the second collimator; and exposing said substrate having the plurality of etched holes to the collimated sputtered material from the deposition plume.

Additional features and advantages of the disclosure will be set forth in the description which follows, and in part will be obvious from the description, or can be learned by practice of the herein disclosed principles. The features and advantages of the disclosure can be realized and obtained by means of the instruments and combinations particularly pointed out in the appended claims. These and other features of the disclosure will become more fully apparent from the following description and appended claims, or can be learned by the practice of the principles set forth herein.

### BRIEF DESCRIPTION OF THE DRAWINGS

In order to describe the manner in which the above-recited and other advantages and features of the disclosure can be obtained, a more particular description of the principles briefly described above will be rendered by reference to specific embodiments thereof which are illustrated in the appended drawings. Understanding that these drawings depict only exemplary embodiments of the disclosure and are not therefore to be considered to be limiting of its scope, the principles herein are described and explained with additional specificity and detail through the use of the accompanying drawings.

FIG. 1 illustrates a prior art focused ion beam used to deposit sputtered material from a target onto a substrate in an ion beam deposition system.

FIG. 2 illustrates a divergent non-uniform sputtered material deposited into etched holes in a substrate using the prior art ion beam deposition system shown in FIG. 1.

FIG. 3 illustrates an embodiment of the present invention wherein a collimated broad ion beam is used to sputter material from a target to a substrate while a collimator is placed between the target and the substrate in an ion beam deposition system.

FIG. 4 illustrates uniform sputtered material deposited into etched holes in a substrate using the ion beam deposition system shown in FIG. 3.

FIG. 5 shows an example of the aspect ratio of the columns of the collimator.

FIG. 6 shows an example of a hexagonal honeycomb shaped holes of the collimator.

Similar reference characters refer to similar parts throughout the several views of the drawings.

### DETAILED DESCRIPTION

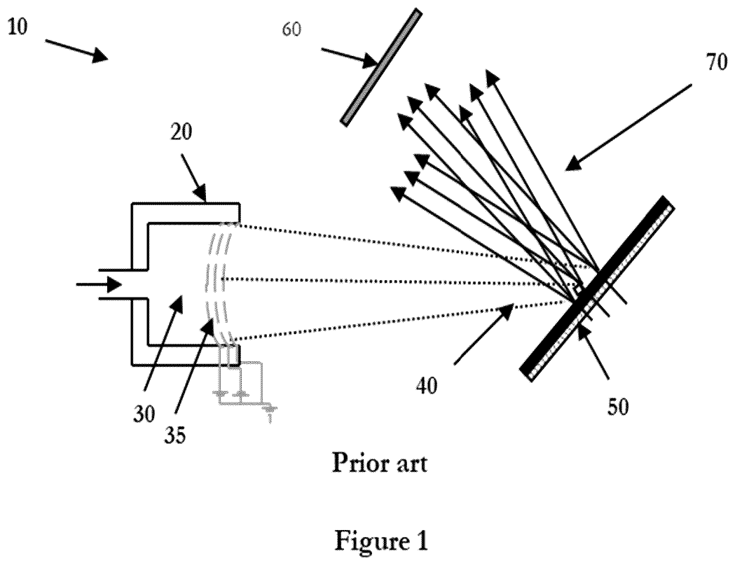

FIG. 1 illustrates a typical prior art ion beam deposition system 10. In an ion beam deposition process, a target 50 is placed in front of an ion source 20. The ion source 20 can be comprised of a plasma chamber 30, and an ion extraction grid system 35. The ion extraction grid system 35 can be comprised of a plurality of conducting plates that have multiple holes therein aligned from plate to plate. The ion extraction grid system 35 extracts ions and helps collimate ion beamlets coming out of each of the holes of the plates, and forms a substantially collimated ion beam 40. Plasma in the plasma chamber 30 may be generated by methods known in the art including direct current (DC) and radio frequency (RF) inductively coupled plasma (ICP) coils. The energy of the ions extracted from the ion source 20 is defined by the voltages applied to the ion extraction grid system 35. The extracted ions in the collimated ion beam 40 impinge on the target 50 causing a sputtering of target material in a deposition plume 70 towards a substrate on the substrate stage 60.

The stage 60 can rotate the substrate about an axis that is perpendicular or nearly perpendicular within +/− ten degrees to the substrate surface. The stage 60 can tilt the substrate with respect to the sputtered material from the deposition plume 70 for at least a portion of the deposition process. The deposition plume 70 of sputtered material from the target 50 can be directed at any angle with respect to the substrate surface by tilting the substrate stage 60. Provisions may be made on the substrate stage 60 to cool the substrate during the deposition process to prevent thermal damage to the devices on the substrate. The substrate may also be heated to a specific temperature to enhance the ion beam deposition process.

In a perfect ion beam deposition system 10 all beamlets and sputtered material in the deposition plume 70 would be perfectly collimated, with no divergence of the ions and/or sputtered material from the intended direction. In such a system 10, all features deposited on the substrate would be perfectly symmetrical. However, practical ion beam deposition systems 10 have non-zero beam divergence and non-zero deposition plume divergence.

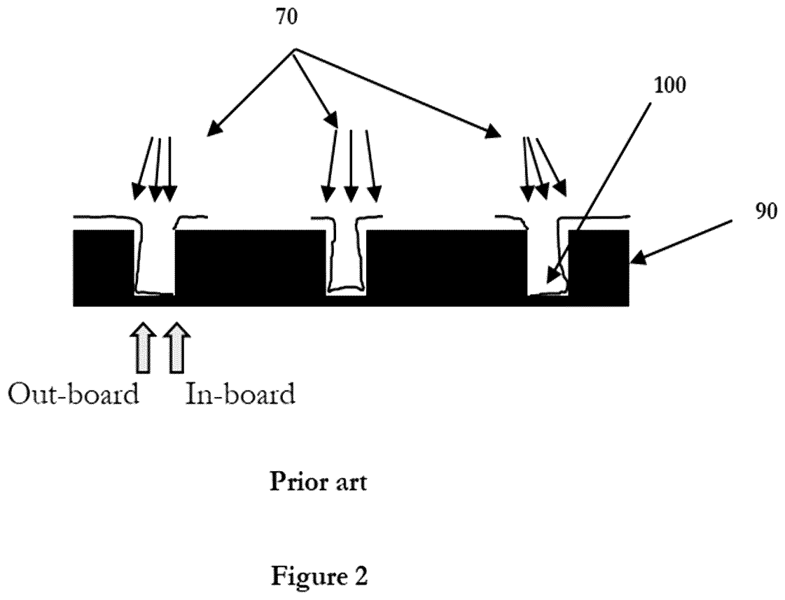

The results of using the prior art ion beam deposition system of FIG. 1 to deposit sputter material onto a substrate is shown in FIG. 2. Due to the divergence of the deposition plume 70, trench sidewalls of etched holes 100 in a substrate 90 get coverage and the deposition has in-board and out-board asymmetry. In practice, ion sources 20 generate an ion beam that is a collection of beamlets with a finite non-zero beam divergence. Further, the sputtered material in the deposition plume 70 has a finite non-zero divergence. A consequence of the sputtered material divergence within the deposition plume 70 is that as the substrate is tilted away from normal sputtered material incidence, there will be more intense deposition on the side of the etched holes 100 of the substrate 90 nearer to the target, and less intense deposition on the side of the etched holes 100 of the substrate 90 farther from the target. By rotating the substrate about an axis, the deposition depths can be made more uniform in the areas of the substrate that are feature free. Devices on the substrates however are typically made of features in 3-dimensions and not flat surfaces. On 3-dimensional features on the substrate, the effect of the sputter species divergence is that the inboard side of the devices on the substrate will experience a different amount of sputtered material exposure from the deposition plume than the outboard side of the devices, and, in this case, rotation of the substrate about its axis does not cause the inboard and outboard asymmetry to be eliminated. This inboard and outboard asymmetry becomes more pronounced as the location of the devices is farther away from the tilt axis of the substrate.

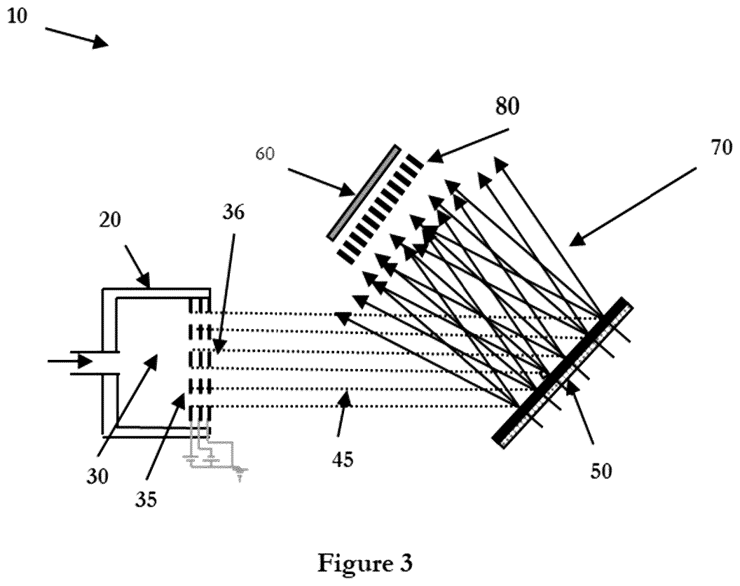

FIG. 3 illustrates an embodiment of the present invention of an ion beam deposition system 10 with a deposition plume 70 collimator 80. In this embodiment of the present invention, a second collimator 80 is provided between the generated deposition plume 70 and the substrate on the substrate stage 60. An ion source 20 can be comprised of a plasma chamber 30 and an ion extraction grid system 35. The ion extraction grid system 35 can be comprised of a plurality of conducting plates that have multiple holes therein aligned from plate to plate using a first collimator 36. The ion extraction grid system 35 can extract the ions from plasma source 30. The generated ion beam 45 can either be focused or non-focused broad beam that is collimated toward the target 50 in a vacuum chamber wherein the broad beam impinges across a surface of the target 50. Plasma in the plasma chamber 30 may be generated by methods known in the art including direct current (DC) and radio frequency (RF) inductively coupled plasma (ICP) coils. The energy of the ions extracted from the ion source 20 is defined by the voltages applied to the ion extraction grid system 35. The second collimator 80 filters out divergent sputtered species from the deposition plume 70.

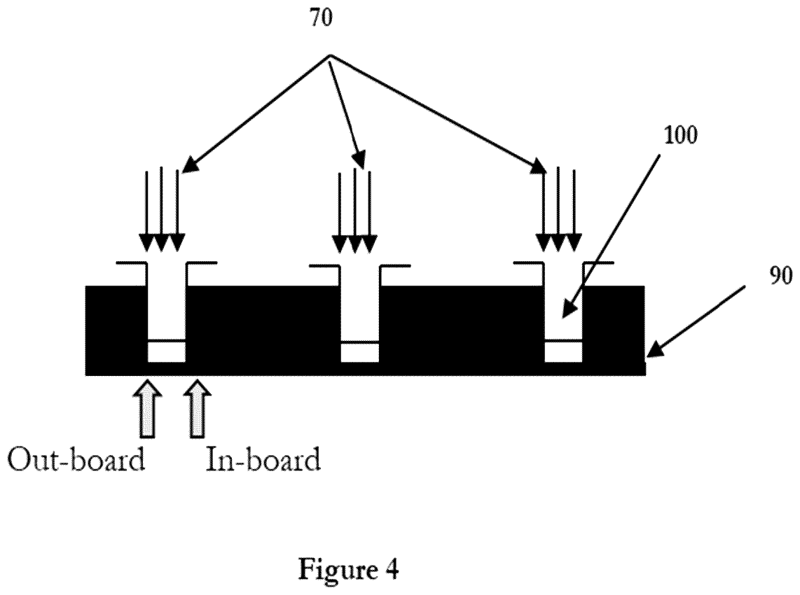

As shown in FIG. 4, the collimated uniform sputtered species of the deposition plume 70 land on the bottom of trenches of the etched holes 100 in the substrate 90. As a result, inboard and outboard asymmetry are reduced due to the use of the second collimator 80 as shown in the embodiment of the present invention of FIG. 3 that reduces the divergent sputter species from the deposition plume 70 generated from the impingement of the ion beam 45 on the target 50 within the ion beam deposition system 10.

In one embodiment of the present invention, a method is provided for depositing sputtered material onto a substrate. The method comprising the steps of placing the substrate onto a substrate stage in a vacuum chamber. Using a plasma source to generate ions within the vacuum chamber. The generated ions are collimated as a broad ion beam from the plasma source using a first collimator. The collimated ions of the collimated broad ion beam are directed at a target within the vacuum chamber. The collimated broad ion beam can be focused or non-focused wherein the collimated broad ion beam impinges on a surface of the target. The collimated broad ion beam can impinge an area of the target that is at least as large as a total area of the substrate or an area of the target that is greater than a total area of the substrate. As a result of the collimated broad ion beam impinging on the target, material from the target is sputtered from the target toward the substrate as part of a deposition plume. The sputtered material within the deposition plume can be collimated using a second collimator that can be placed between the target and the substrate within the vacuum chamber. The substrate is exposed to the collimated sputtered material from the deposition plume. The substrate can be rotated using the substrate stage during at least a portion of the deposition of the collimated sputter material onto the substrate. The rotation speed of the substrate can be up to five hundred RPM's during at least a portion of the deposition of the collimated sputter material onto the substrate. The substrate stage with the substrate can be tilted at no greater than +/− five degrees relative to the collimator during at least a portion of the deposition of the collimated sputter material onto the substrate. The substrate stage with the substrate can be scanned relative to the collimator during at least a portion of the deposition of the collimated sputter material onto the substrate. The scanning speed of the substrate relative to the collimator can be up to ten meters per second during at least a portion of the deposition of the collimated sputter material onto the substrate. The substrate stage and the collimator can move relative to one another during at least a portion of the deposition of the collimated sputter material onto the substrate. The second collimator can be placed between the substrate and the target in such a way that that the second collimator does not impinge on the path of collimated ions from the ion source to the target during at least a portion of the exposure step. The second collimator may be placed anywhere in the path of the sputtered material from the target to the substrate. The second collimator may be brought into position during a portion of the deposition.

In another embodiment of the present invention, a method is provided for depositing material onto a substrate. The method comprising the steps of placing the substrate having a plurality of etched holes onto a substrate stage in a vacuum chamber. Using a plasma source to generate ions within the vacuum chamber. The generated ions are collimated as a broad ion beam from the plasma source using a first collimator. The collimated ions of the collimated broad ion beam are directed at a target within the vacuum chamber. The collimated broad ion beam can be non-focused wherein the collimated broad ion beam impinges on a surface of the target. The collimated broad ion beam can impinge an area of the target that is at least as large as a total area of the substrate or an area of the target that is greater than a total area of the substrate. As a result of the collimated broad ion beam impinging on the target, material from the target is sputtered from the target toward the substrate having a plurality of etched holes as part of a deposition plume. The sputtered material within the deposition plume can be collimated using a second collimator that can be placed between the target and the substrate within the vacuum chamber. The substrate having a plurality of etched holes can be exposed to the sputtered material from the deposition plume. The substrate can be rotated using the substrate stage during at least a portion of the deposition of the collimated sputter material onto the substrate. The substrate can be rotated using the substrate stage during at least a portion of the deposition of the sputtered material onto the substrate having a plurality of etched holes. The rotation speed of the substrate can be up to five hundred RPMs during at least a portion of the deposition of the sputtered material onto the substrate having a plurality of etched holes. The substrate stage with the substrate can be tilted at no greater than +/− five degrees relative to the target during at least a portion of the deposition of the sputtered material onto the substrate having a plurality of etched holes. The substrate stage with the substrate having a plurality of etched holes can be scanned relative to the target during at least a portion of the deposition of the sputtered material onto the substrate having a plurality of etched holes. The scanning speed of the substrate relative to the target can be up to ten meters per second during at least a portion of the deposition of the sputtered material onto the substrate having a plurality of etched holes.

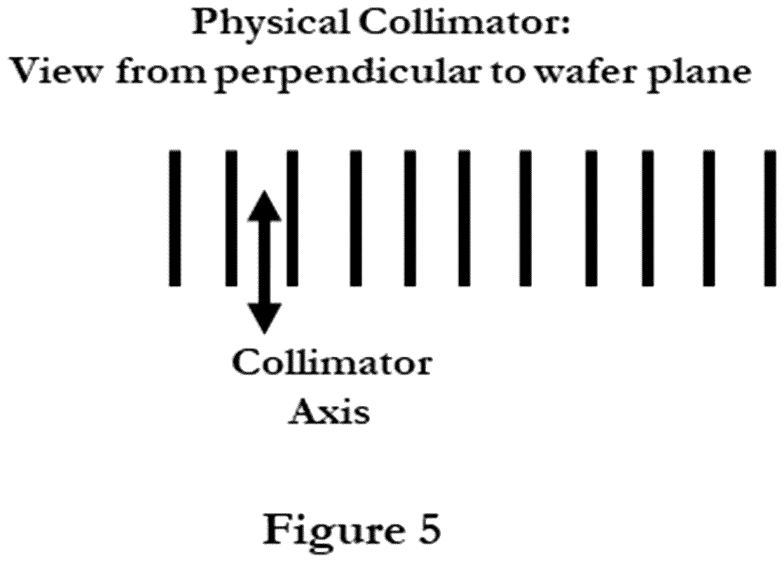

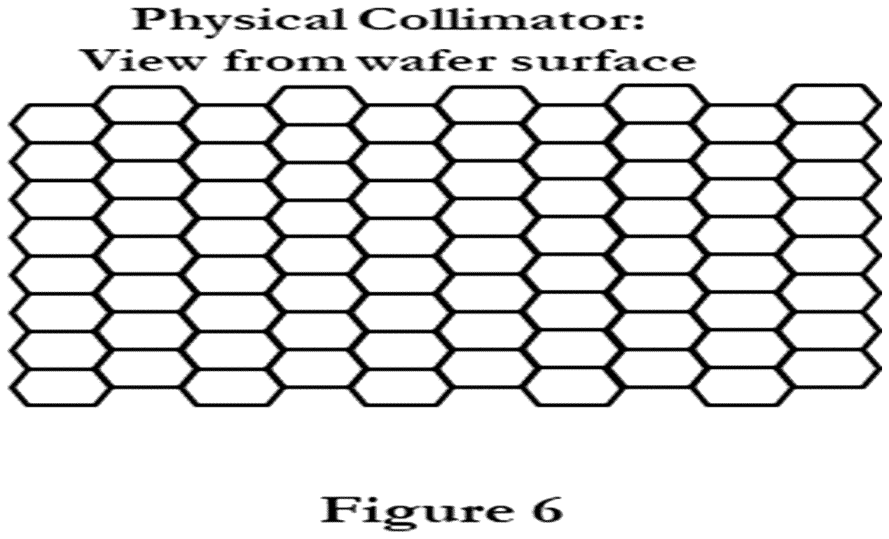

Illustrations of the collimator are shown in FIGS. 5 and 6. FIG. 5 shows an example of the aspect ratio of the columns of the collimator. Whereas, FIG. 6 shows an example of a hexagonal honeycomb shaped holes of the collimator. Hexagonal honeycomb collimators are preferred since the shape maximizes the surface area of the openings in the collimator. Other shapes of the collimator opening may also be used. Aspect ratio of the holes, ratio of the length of the holes to the diameter of the holes, may be as high 10 to 1. Degree of collimation of the sputtered uncollimated plume depends on the aspect ratio of the physical collimator. The divergence of the 10:1 aspect ratio collimated sputtered plume is very low at less than six degrees, whereas 1:1 aspect ratio collimator allows divergence of nearly sixty degrees. The choice of aspect ratio of the physical collimator is made by the deposition material structure on the substrate, and the degree of reduction of the sidewall coverage compared to trench bottom coverage. Lower aspect ratio of the collimator gives higher amount of sidewall coverage. Diameter of the collimator holes maybe as small as one millimeter, and may be as large as one centimeter. Collimator may or may not be actively cooled by running cooling liquid channels around the outer periphery of the collimator structure. The inner walls of the collimator holes, and the overall surface of the collimator is preferred to be not smooth, in order to make the divergent sputtered particles to stick to the collimator surfaces. The collimator can have a surface area at least as large as a surface area of the substrate.

Although a variety of examples and other information was used to explain aspects within the scope of the appended claims, no limitation of the claims should be implied based on particular features or arrangements in such examples, as one of ordinary skill would be able to use these examples to derive a wide variety of implementations. Further, and although some subject matter may have been described in language specific to examples of structural features and/or method steps, it is to be understood that the subject matter defined in the appended claims is not necessarily limited to these described features or acts. For example, such functionality can be distributed differently or performed in components other than those identified herein. Rather, the described features and steps are disclosed as examples of components of systems and methods within the scope of the appended claims. Moreover, claim language reciting “at least one of” a set indicates that one member of the set or multiple members of the set satisfy the claim.

What is claimed is:

1. A method for depositing material onto a substrate, comprising the steps of:
placing the substrate onto a substrate stage in a vacuum chamber;
generating ions using a plasma source within the vacuum chamber;
collimating the generated ions from the plasma source using a first collimator;
directing a collimated broad ion beam of the collimated ions at a target within the vacuum chamber;
sputtering material from the target toward the substrate as part of a deposition plume using the collimated broad ion beam;
placing a second collimator between the target and the substrate within the vacuum chamber;
collimating the sputtered material from the deposition plume using the second collimator; and
exposing the substrate to the collimated sputtered material from the deposition plume.

2. The method of claim 1, wherein the collimated broad ion beam further comprising a non-focused collimated broad ion beam.

3. The method of claim 2, wherein the collimated non-focused broad ion beam impinges an area of the target that is at least as large as a total area of the substrate.

4. The method of claim 2, wherein the collimated non-focused broad ion beam impinges an area of the target that is greater than a total area of the substrate.

5. The method of claim 1, further comprising rotating the substrate stage with the substrate during at least a portion of the exposure step.

6. The method of claim 5, wherein rotating the substrate stage with the substrate is at a rotation speed up to five hundred RPMs during at least a portion of the exposure step.

7. The method of claim 1, further comprising tilting the substrate stage with the substrate at no greater than +/− five degrees relative to the second collimator during at least a portion of the exposure step.

8. The method of claim 1, further comprising scanning the substrate stage with the substrate relative to the second collimator during at least a portion of the exposure step.

9. The method of claim 8, wherein scanning the substrate stage with the substrate is at a scanning speed up to ten meters per second during at least a portion of the exposure step.

10. The method of claim 8, wherein both the substrate stage and the second collimator move relative to one another during at least a portion of the exposure step.

11. The method of claim 1, wherein the second collimator is placed between the substrate and the target in such a way that the second collimator does not impinge on the collimated ions from the ion source to the target during at least a portion of the exposure step.

12. The method of claim 1, wherein the second collimator further comprising a plurality of hexagonal honeycomb shaped holes.

13. The method of claim 1, wherein the second collimator further comprising a surface area at least as large as a total surface area of the substrate.

14. The method of claim 1, wherein the second collimator further comprising a surface area greater than a total surface area of the substrate.

15. A method for depositing material onto a substrate, comprising the steps of:
placing the substrate having a plurality of etched holes onto a substrate stage in a vacuum chamber;
generating ions using a plasma source within the vacuum chamber;
collimating the generated ions from the plasma source using a first collimator;
directing a non-focused collimated broad ion beam of the collimated ions at a target within the vacuum chamber;
sputtering material from the target toward said substrate having the plurality of etched holes as part of a deposition plume using the non-focused collimated broad ion beam;
placing a second collimator between the target and sad substrate having the plurality of etched holes within the vacuum chamber;
collimating the sputtered material from the deposition plume using the second collimator; and
exposing said substrate having the plurality of etched holes to the collimated sputtered material from the deposition plume.

16. The method of claim 15, further comprising rotating the substrate stage with said substrate having the plurality of etched holes during at least a portion of the exposure step.

17. The method of claim 16, wherein rotating the substrate stage with said substrate having the plurality of etched holes at a rotation speed up to five hundred RPMs during at least a portion of the exposure step.

18. The method of claim 15, further comprising tilting the substrate stage with said substrate having the plurality of etched holes at no greater than +/− five degrees relative to the deposition plume during at least a portion of the exposure step.

19. The method of claim 15, further comprising scanning the substrate stage with said substrate having the plurality of etched holes relative to the deposition plume during at least a portion of the exposure step.

20. The method of claim 19, wherein scanning the substrate stage with said substrate having the plurality of etched holes at a scanning speed up to ten meters per second during at least a portion of the exposure step.
